(19) United States
(12) Patent Application Publication
(10) Pub. No.: US 2026/0047011 A1
(43) Pub. Date: Feb. 12, 2026

(54) ELECTRONIC DEVICE

(71) Applicant: DENSO CORPORATION, Kariya-city (JP)

(72) Inventor: Kei SANADA, Kariya-city (JP)

(21) Appl. No.: 19/253,045

(22) Filed: Jun. 27, 2025

(30) Foreign Application Priority Data
Aug. 7, 2024 (JP) 2024-131075

(51) Int. Cl. H05K 1/18; H01F 27/29; H05K 1/11

(52) U.S. Cl. CPC H05K 1/189; H01F 27/292; H05K 1/111; H05K 2201/10015; H05K 2201/1003; H05K 2201/10166

(57) ABSTRACT

An electronic device includes a substrate having lands and an inductor component that has cores and coils disposed on the cores, respectively. Solder joins the coils and the lands. The coils are arranged in a first direction orthogonal to a thickness direction of the substrate. The lands joined to the coils include mounting lands provided in correspondence with the coils and forming a circuit together with the coils. At least one stress-relief land is provided at a position separated from the mounting lands.

### CROSS REFERENCE TO RELATED APPLICATION

This application is based on and claims the benefits of priority of Japanese Patent Application No. 2024-131075 filed on Aug. 7, 2024. The entire disclosure of which is incorporated herein by reference.

### TECHNICAL FIELD

The disclosure herein relates to an electronic device.

### BACKGROUND

A coupled inductor includes a core and coils arranged on the core and magnetically coupled to each other.

### SUMMARY

According to at least one embodiment, an electronic device includes a substrate having lands and an inductor component that has cores and coils disposed on the cores, respectively. Solder joins the coils and the lands. The coils are arranged in a first direction orthogonal to a thickness direction of the substrate. The lands joined to the coils include mounting lands provided in correspondence with the coils and forming a circuit together with the coils. At least one stress-relief land may be provided at a position separated from the mounting lands.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a circuit diagram illustrating a multiphase power supply to which an electronic device according to a first embodiment.

FIG. 2 is a diagram illustrating an example of an ECU equipped with the multiphase power supply.

FIG. 3 is a plan view illustrating an example of the electronic device.

FIG. 4 is a perspective view illustrating a coupled inductor.

FIG. 5 is a plan view of the coupled inductor as viewed from a top side.

FIG. 6 is a plan view of the coupled inductor as viewed from a bottom side.

FIG. 7 is a perspective view illustrating a core.

FIG. 8 is a perspective view illustrating a coil.

FIG. 9 is a cross-sectional view taken along a line IX-IX of FIG. 5.

FIG. 10 is a diagram illustrating a positional relationship between a terminal and a land.

FIG. 11 is a cross-sectional view taken along a line XI-XI of FIG. 10.

FIG. 12 is a cross-sectional view taken along a line XII-XII of FIG. 10.

FIG. 13 is a diagram illustrating effects of substrate distortion in a reference example.

FIG. 14 is a diagram illustrating a positional relationship between a terminal and a land in the reference example.

FIG. 15 is a diagram illustrating effects of parasitic inductance due to an extension portion in the reference example.

FIG. 16 is a diagram illustrating effects of parasitic inductance due to a stress-relief land.

FIG. 17 is a diagram illustrating a modification.

FIG. 18 is a cross-sectional view showing a vicinity of a coupled inductor in an electronic device according to a second embodiment.

### DETAILED DESCRIPTION

To begin with, examples of relevant techniques will be described.

A coupled inductor according to a comparative example includes a core and coils that are arranged on the core and magnetically coupled to each other. In applications where a relatively large current flows, the coil is constructed using a metal plate instead of a wire. Therefore, in the coupled inductor of the comparative example, the multiple coils are arranged in a predetermined direction, and a size of the coupled inductor increases in the direction in which the coils are aligned. An impact of substrate strain on a solder that joins a substrate's land and the coil increases, potentially shortening the solder's lifespan when the coupled inductor is mounted on a substrate. It should be noted that not only in coupled inductors but also in inductor components that include multiple coils arranged in a predetermined direction, the impact of substrate strain on the solder that joins the land and the coils increases, potentially shortening the solder's lifespan. In the viewpoint described above, or in another viewpoint not mentioned, the electronic device is required to be further improved.

In contrast to the comparative example, according to an electronic device of the present disclosure, a solder lifespan can be improved.

According to one aspect of the present disclosure, an electronic device includes a substrate having lands and an inductor component that has cores and coils disposed on the cores, respectively. Solder joins the coils and the lands. The coils are arranged in a first direction orthogonal to a thickness direction of the substrate. The lands joined to the coils include mounting lands provided in correspondence with the coils and forming a circuit together with the coils. At least one stress-relief land is provided at a position separated from the mounting lands.

According to this configuration, in addition to the mounting lands, the stress-relief land is intentionally provided. By providing the stress-relief land, bonding points and bonding area of the inductor component to the substrate 30 are increased. By adding the stress-relief land, while employing the inductor component configuration in which the coils are aligned in the first direction, the stress exerted on the solder due to substrate distortion can be alleviated, thereby improving the solder lifespan.

Hereinafter, multiple embodiments will be described with reference to the drawings. The same or corresponding elements in the embodiments are assigned the same reference numerals, and redundant descriptions thereof may be omitted. When only a part of the configuration is described in one embodiment, the other parts of the configuration may employ descriptions about a corresponding configuration in another embodiment preceding the one embodiment. Further, not only the combinations of the configurations explicitly shown in the description of the respective embodiments, but also the configurations of the plurality of embodiments can be partially combined even when they are not explicitly shown as long as there is no difficulty in the combination in particular.

### First Embodiment

An electronic device according to the present embodiment includes an inductor component, such as a coupled inductor, which comprises multiple coils (inductors) as described below. Such an electronic device can be applied to various electronic circuits, such as power supply circuits and high-frequency circuits. The electronic device may be used, for example, in configurations that utilize multiple inductors with an aim of reducing size and cost. The following describes an example where the electronic device is applied to a multiphase power supply.

### <Multiphase Power Supply>

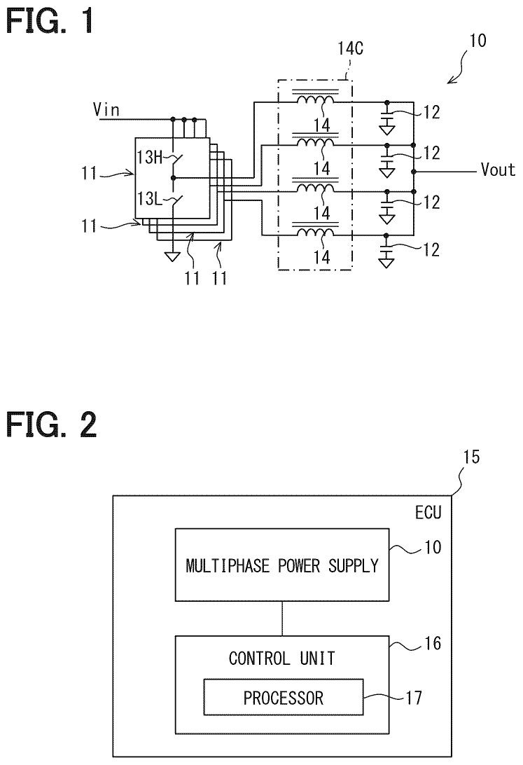

FIG. 1 is a circuit diagram illustrating a multiphase power supply to which an electronic device according to a first embodiment. For convenience, FIG. 1 shows a simplified representation of some parts of the multiphase power supply.

The multiphase power supply 10 shown in FIG. 1 is a buck-type DCDC converter or step-down DCDC converter. The multiphase power supply 10 steps down an input voltage Vin to a predetermined voltage and outputs it as an output voltage Vout. The multiphase power supply 10 includes multiple power circuits 11 and a capacitor 12.

A power circuit 11 is a switching power circuit. The power circuit 11 is sometimes referred to as a phase, a stage, or a channel (Ch). The number of power circuits 11 is sometimes referred to as the number of phases, stages, or channels. The power circuit 11 includes switching elements 13H, 13L, and an inductor 14. The switching elements 13H, 13L may be, for example, MOSFETs or IGBTs. The switching elements 13H, 13L could also be bipolar transistors. MOSFET is an abbreviation for Metal Oxide Semiconductor Field Effect Transistor. The IGBT is an abbreviation of an insulated gate bipolar transistor.

The switching elements 13H, 13L are connected in series between a power supply line, to which an input voltage Vin is applied, and a ground (GND) line, with the switching element 13H on a high side. One end of the inductor 14 is connected to a connection point (midpoint) of the switching elements 13H, 13L. The other end of the inductor 14 is connected to an output line.

The power circuits 11 are connected in parallel with each other. The power circuits 11 are arranged in parallel with each other to supply the output voltage Vout to a load (not shown). In the power circuits 11, power supply lines are interconnected. In the power circuits 11, the output lines are interconnected. By paralleling the power circuits 11, the output current from the multiphase power supply 10, that is, a load current, can be increased. The number of multiple power circuits 11 is not particularly limited. The multiphase power supply 10 is equipped with four (four-phase) power circuits 11.

The capacitor 12 is connected to the output line. A positive terminal of the capacitor 12 is connected to the output line. A negative terminal of the capacitor 12 is connected to ground. The capacitor 12 may be provided individually for each power circuit 11, or it may be provided commonly for the power circuits 11. In the multiphase power supply 10, the capacitor 12 is provided individually for each power circuit 11.

The multiphase power supply 10 includes a coupled inductor 14C. In the coupled inductor 14C, the coils constituting each inductor 14 are arranged on a common core. A single coupled inductor 14C provides multiple inductors 14 that constitute multiple power circuits 11. The coils are wound on the common core. As a result, magnetic fields cancel each other out between phases, allowing an effective inductance value to be reduced.

The multiphase power supply 10 may be equipped with a power control circuit (not shown). The power control circuit performs voltage mode control based on feedback of the output voltage Vout, for example, and controls operation of the switching elements 13H, 13L. In the voltage mode control, a pulse width (duty cycle) of a PWM signal is determined based on the output voltage Vout, and the output voltage Vout of the multiphase power supply 10 is controlled. It should be noted that current mode control may be implemented instead of the voltage mode control.

The power control circuit synchronizes the operation of the power circuits 11 so that the power circuits 11 perform switching operations at different phases from each other. By using multiple phases in this manner, it is possible to increase a switching frequency in a pseudo manner even if the switching frequency is the same in each of the power circuits 11. As a result, it is possible to reduce ripple in the output voltage and improve responsiveness. The power supply control circuit switches the power circuit 11 to be switched, that is, the number of drive phases, depending on the load current. The power control circuit compares the load current with a threshold current and increases and/or decreases the number of driving phases based on the comparison result.

FIG. 2 shows an application example of the multiphase power supply 10. The multiphase power supply 10 is applied, for example, to an ECU 15. “ECU” is an abbreviation of “Electronic Control Unit”. The ECU 15 includes the multiphase power supply 10 and a control unit 16. The ECU 15 may be installed, for example, in a moving object. Examples of the moving object include a vehicle, a flying object, a ship, a construction machine, and an agricultural machine. The moving object may be manned or unmanned.

The exemplary ECU 15 is installed in a vehicle. The ECU 15 may be, for example, an automated driving ECU or an ADAS ECU that executes control to assist the driver's driving operations. “ADAS” is an abbreviation for “Advanced Driving Assistant System”. For example, levels 3 to 5 as defined by the Society of Automotive Engineers (SAE International) correspond to automatic driving levels, while levels 1 to 2 correspond to driving assistance levels. The ECU 15 may also be an infotainment ECU or a cockpit ECU. A cockpit ECU is an ECU that controls devices such as a meter device, a navigation device, and an air conditioning device.

The multiphase power supply 10 provides power to the control unit 16. The control unit 16 operates upon receiving the power supply. The exemplary control unit 16 includes a processor 17 and a memory (not shown). The processor is, for example, a CPU, GPU, or the like. “CPU” is an abbreviation for “Central Processing Unit”. “GPU” is an abbreviation for “Graphics Processing Unit”. The control unit 16 may be realized by combining multiple types of calculation processing devices such as a CPU, an MPU, and a GPU. The processor 17 executes predetermined control processes by running a control program stored in memory.

A core voltage of the processor 17 is around 1[V] (for example, less than 1[V]), and the load current is several tens of amperes or more (for example, 100 [A] or more). In order to accommodate such low voltage and high current, the ECU 15 employs the multiphase power supply 10 as its power circuit. The multiphase power supply 10 steps down the input voltage Vin to a voltage corresponding to the core voltage of the processor 17 and outputs it as the output voltage Vout. By using the multiphase power supply 10, it is possible to support enhanced performance of the processor 17 required for improvements in the automatic driving levels and evolution of infotainment functions, particularly accommodating automatic driving level 3 and above.

In high-performance processors 17, current consumption fluctuates sharply in response to computational processing. Therefore, to ensure a stable voltage supply even during sudden load changes, a large number of capacitors 12 are required. By using the coupled inductor 14C, the magnetic fields between the phases cancel each other out as described above, thereby reducing the effective inductance value. This improves the responsiveness during sudden load changes. Therefore, compared to a configuration using conventional single inductors, the number of capacitors 12 can be significantly reduced. For example, the size of the ECU 15 can be reduced.

### <Outline Configuration of Electronic Device>

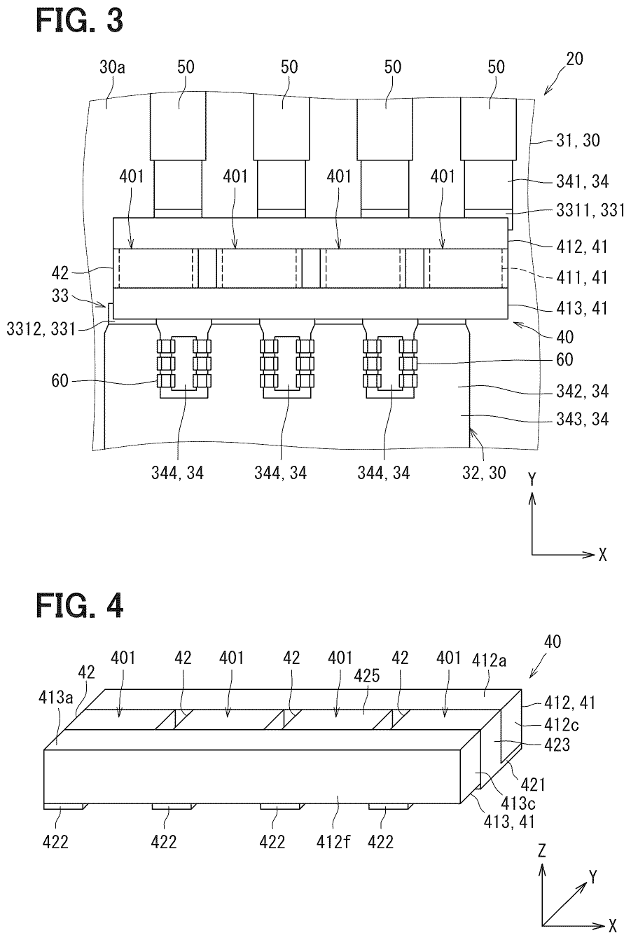

FIG. 3 is a plan view illustrating an example of the electronic device. FIG. 3 is an enlarged view of an area around the coupled inductor within the electronic device. For convenience, FIG. 3 shows a solder resist omitted. Additionally, lands other than those corresponding to the coupled inductor are omitted.

The electronic device 20 includes a substrate 30 and components mounted on the substrate 30. The components includes a coupled inductor 40, a switching device 50, and a capacitor 60. The electronic device 20 provides the aforementioned multiphase power supply 10. The electronic device 20 may also provide an ECU 15. In this case, a processor 17 is also mounted on the substrate 30.

Hereinafter, a thickness direction of the substrate is referred to as a Z-direction. A direction perpendicular to the Z-direction and in which multiple coils are aligned is referred to as an X-direction. A direction orthogonal to both the Z-direction and the X-direction is referred to as a Y-direction. Unless otherwise specified, a shape viewed in a plane from the Z-direction, that is, a shape along an XY plane defined by the X-direction and Y-direction is referred to as a planar shape. A plan view from the Z-direction may be simply referred to as a plan view.

The substrate 30 may be referred to as a printed circuit board, printed wiring board, or wiring board. The substrate 30 includes an insulating base 31 and a conductor 32. The insulating base 31 is formed using an electrically insulating material such as resin. The conductor 32 is arranged on the insulating base 31. At least a portion of the conductor 32 forms a circuit together with the components mounted on the substrate 30.

The conductor 32 includes a land 33 and a wire 34. The land 33, functioning as a land corresponding to the coupled inductor 40, is arranged on a surface layer of the insulating base 31 and includes a mounting land 331 that provides a wiring function. The mounting land 331 is arranged on the surface layer on one side 30a of the substrate 30. The mounting land 331 includes mounting lands 3311, 3312. The mounting land 3311 is provided at a position separated from the mounting land 3312 in the Y-direction. The mounting land 331 is provided at an end of the wire 34. The conductor 32 may have a via conductor. The via conductor is formed by disposing a conductor such as plating in a through-hole (via) formed in an insulating layer constituting the insulating base 31. The via conductor electrically connects wires 34 of different layers.

The wire 34 is formed, for example, by patterning a metal foil. The wire 34 is disposed on at least the surface layer on the side of one surface 30a. The wire 34 may be disposed not only on the surface layer on one surface 30a side but also on the surface layer on the rear side, or it may be disposed inside the insulating substrate 31. The substrate 30 may be a single-sided substrate, a double-sided substrate, or a multilayer substrate containing three or more layers of wiring. The wires 34 includes wires 341, 342, 343, 344.

The wire 341 electrically connects an inductor 401 (coil 42) and the switching device 50. The wire 341 is provided for each inductor 401. The mounting land 331 is provided at one end of the wire 341. The wire 341 extends in the Y-direction. The wires 341 are arranged in the X-direction.

The wire 342 electrically connects the inductor 401 (coil 42) and the capacitor 60. The wire 342 is provided for each inductor 401. The wire 342 extends in the Y-direction. The wires 342 are arranged in the X-direction. The wire 342 is provided at a position separated from the wire 341 in the Y-direction. In the Y-direction, a coupled inductor 40 is positioned between the wire 342 and the wire 341.

The wire 343 electrically connects the inductor 401 and the capacitor 60 to the output terminal of the multiphase power supply. The wire 343 is connected to the wires 342. The wire 343 serves as a common wiring for the wires 342. The wires 342 are connected to the wire 343. The wire 344 is a ground wire. The wire 344 is electrically connected to an inner layer ground wiring via a via conductor (not shown), for example. The wire 344 is arranged between adjacent wires 342. The wire 344 and the wire 343 are alternately arranged in the X-direction. The wire 34 includes three wires 344. Details regarding a land structure corresponding to the coupled inductor 40 will be described later.

The coupled inductor 40 is arranged on one surface 30a of the substrate 30. The coupled inductor 40 provides the coupled inductor 14C. The coupled inductor 40 is an inductor component that includes a core 41 and coils 42. The coupled inductor 40 includes four coils 42. The coils 42 are arranged in the X-direction. The coupled inductor 40 includes inductors 401. One end of the coil 42 is soldered to the mounting land 3311, and the other end of the coil 42 is soldered to the mounting land 3312. Details of a structure of the coupled inductor 40 will be described later.

The switching device 50 provides the switching elements 13H, 13L. The switching device 50 is provided correspondingly to the coil 42, specifically the inductor 401. The switching device 50 constitutes the switching elements 13H, 13L for one phase. A single switching device 50 constitutes a driver for one phase. Alternatively, the switching device 50 may be provided for each of the switching elements 13H, 13L. Multiple switching devices 50 are arranged in the X-direction. The switching device 50 and the coupled inductor 40 are arranged in the Y-direction. The switching device 50 is soldered at the end on a side of the switching device 50 to the wire 341.

The capacitor 60 provides the capacitor 12. The capacitors 60 are provided for each inductor 401. The capacitor 60 is, for example, a chip capacitor. The capacitors 60 corresponding to each inductor 401 are arranged in the X-direction. In the Y-direction, a coupled inductor 40 is positioned between the switching device 50 and the capacitor 60. One terminal of the capacitor 60 is soldered to the wire 342, and the other terminal is soldered to the wire 344.

### <Coupled Inductor>

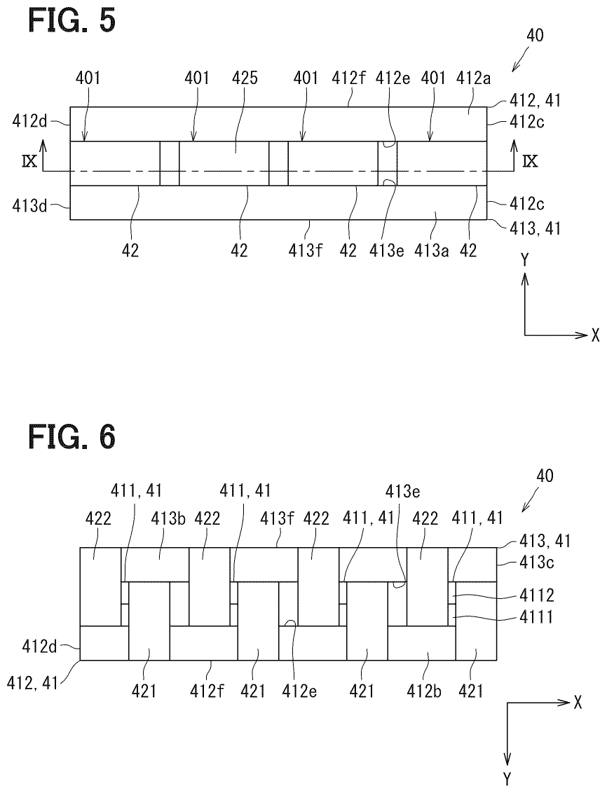

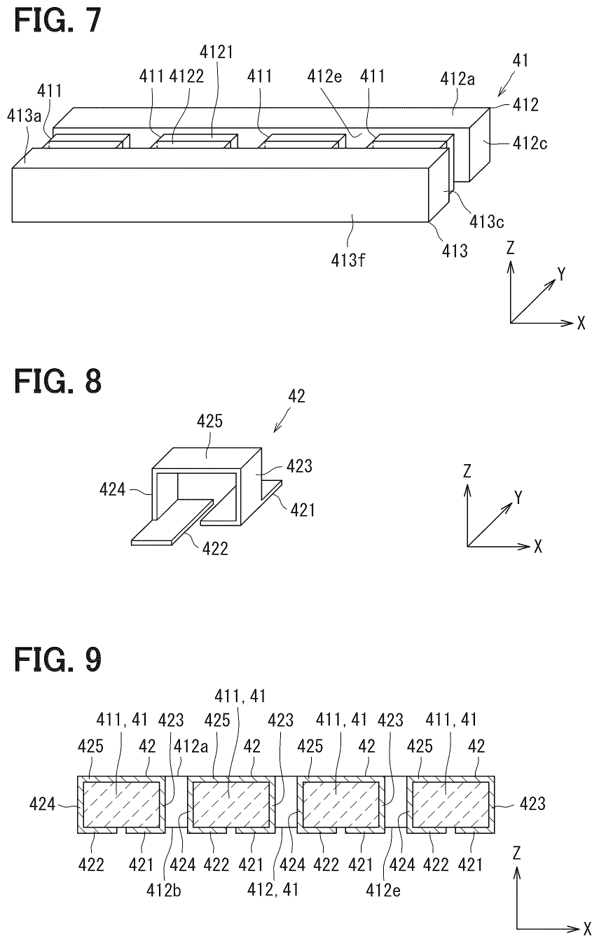

FIG. 4 is a perspective view illustrating a coupled inductor. FIG. 5 is a plan view of the coupled inductor as viewed from a top side. FIG. 6 is a plan view of the coupled inductor as viewed from a bottom side. FIG. 7 is a perspective view illustrating a core. FIG. 8 is a perspective view illustrating a coil. FIG. 9 is a cross-sectional view taken along a line IX-IX of FIG. 5.

As described above, a single coupled inductor 40 provides multiple inductors 401. The coupled inductor 40 has the core 41 and the coils 42. The coils 42 are arranged on a single core 41, i.e., a common core 41, and are magnetically coupled to each other. By using the coupled inductor 40, a magnetic flux between phases can cancel each other out, thereby reducing the effective inductance.

The core 41 is formed using a magnetic material such as ferrite. The core 41 functions as a magnetic circuit. The core 41 has multiple central cores 411, an end core 412, and an end core 413. The core 41 has the coil 42 inserted through it. A central core 411 is provided individually with respect to the coil 42. The coil 42 is wound around the central core 411. The central core 411 extends in the Y-direction. Multiple central cores 411 are arranged in the X-direction with a predetermined spacing. The core 41 has four central cores 411. Each central core 411 is approximately in the shape of a rectangular parallelepiped shape. The four central cores 411 have the same shape as each other.

The central core 411 may be of a single structure or may be composed of multiple members. The central core 411 is configured to be divided at a center position in the Y-direction. The central core 411 includes a core portion 4111 and a core portion 4112. The core portion 4111 is connected to the end core 412. The core portion 4111 extends from a lateral surface 412e of the end core 412 towards the end core 413. The core portion 4112 is connected to the end core 413. The core portion 4112 extends from a lateral surface 413e of the end core 413 towards the end core 412. The core portion 4111 and the core portion 4112 are fixed, for example by adhesion, with their tips facing each other. The core portion 4111 and the core portion 4112 together form the central 411.

It should be noted that a division position is not limited to the center. It is also possible to configure the single core 411 to be continuous with one of the end cores 412 or 413 and adhered to the other. Both ends of the single core 411 may be adhered to the respective end cores 412, 413.

The end cores 412,413 are positioned opposite each other in the Y-direction. The end cores 412, 413 have the core 411 positioned between them. The end cores 412, 413 extend in the X-direction, which is the alignment direction of the central core 411. One end of each of the central cores 411 is connected to the end core 412, and the other end of each of the central cores 411 is connected to the end core 413. The end cores 412, 413 magnetically connect the central cores 411. The end cores 412, 413 have the same shape as each other. The end cores 412, 413 have a substantially rectangular parallelepiped shape with the X-direction as a longitudinal direction.

The end core 412 has an upper surface 412a, a lower surface 412b, and lateral surfaces 412c, 412d, 412e, and 412f. The end core 413 has an upper surface 413a, a lower surface 413b, and lateral surfaces 413c, 413d, 413e, and 413f. The lower surfaces 412b and 413b are surfaces on the substrate 30 side in the Z-direction. The upper surfaces 412a and 413a are surfaces opposite to the lower surfaces 412b and 413b in the Z-direction. The lateral surfaces 412c and 413c are surfaces opposite to the lateral surfaces 412d and 413d in the X-direction. The lateral surfaces 412e and 413e are surfaces that face each other in the Y-direction. The lateral surfaces 412f and 413f are surfaces opposite to the lateral surfaces 412e and 413e in the Y-direction.

The coil 42 is formed using a metal material with good conductivity, such as copper. The coil 42 is formed not by using a metal wire, but by processing a metal plate material. The metal plate material is sometimes referred to as a metal frame. The coils 42 are formed using the same material and have the same shape as each other. The coils 42 have approximately equal inductance. The coils 42 are arranged in the X-direction with a predetermined interval between them. The coils 42 are aligned in the same orientation. The coils 42 are fixed to the core 41, for example, by adhesive bonding.

The coils 42 are formed by bending a metal plate material of a predetermined thickness. The coils 42 each have terminals 421 and 422, side walls 423 and 424, and an upper wall 425. The terminals 421 and 422 are external connection terminals of the coil 42 and are soldered to the corresponding lands 33. A plate thickness direction of the terminals 421 and 422 is approximately parallel to the Z-direction, and a plate surfaces (lower surfaces) of the terminals 421 and 422 face one surface 30a of the substrate 30. The terminals 421 and 422 extend in the Y-direction. The terminals 421 and 422 have a substantially rectangular planar shape with the Y-direction as a longitudinal direction. The terminals 421 and 422 are arranged side by side in the X-direction with a predetermined spacing. A part of a lateral surface of the terminal 421 and a part of a lateral surface of the terminal 422 face each other in the X-direction. The terminal 421 extends in the Y-direction from a portion facing the terminal 422, specifically toward the lateral surface 412f, i.e., the switching device 50 side. The terminal 422 extends in the Y-direction from a portion facing the terminal 421, specifically toward the lateral surface 413f, i.e., the capacitor 60 side.

The side wall 423 is connected to a portion of the terminal 421 that faces the terminal 422. The side wall 423 is bent at an angle of approximately 90 degrees relative to the terminal 421. A plate thickness direction of the side wall 423 is approximately parallel to the X-direction. The side wall 423 has a width equal to facing portions of the terminals 421 and 422, and extends in the Z-direction. Similarly, the side wall 424 is connected to a portion of the terminal 422 that faces the terminal 421. The side wall 424 is bent at an angle of approximately 90 degrees relative to the terminal 422. A plate thickness direction of the side wall 424 is approximately parallel to the X-direction. The side wall 424 has a width equal to facing portions of the terminals 421 and 422, and extends in the Z-direction, which is the same direction as the side wall 423. Lower ends of the side walls 423 and 424 are connected to the terminals 421 and 422.

The upper wall 425 bridges the side walls 423 and 424. The upper wall 425 extends in the X-direction. One end of the upper wall 425 is connected to an upper end of the side wall 423, and the other end is connected to the upper end of the side wall 424. The upper wall 425 has the same width as the side walls 423 and 424. In a plan view, the upper wall 425 encompasses an entire area of opposing portions of the side walls 423 and 424, as well as the terminals 421 and 422.

The opposing portions of the terminals 421 and 422, the side walls 423 and 424, and the upper wall 425 surround the central core 411. The opposing portions of the terminals 421 and 422, the side walls 423 and 424, and the upper wall 425 are mounted on and wound around the central core 411. In extended portions, excluding the opposing portions of the terminals 421 and 422, the end cores 412, 413 are positioned. The lower surfaces 412b, 413b of the end cores 412, 413 may be positioned above the plate surfaces (upper surfaces) of the terminals 421, 422. By providing recesses in the lower surfaces 412b, 413b to accommodate the extended portions of the terminals 421, 422, the positions of the lower surfaces 412b, 413b may be made approximately flush with the lower surfaces of the terminals 421, 422.

In the adjacent coils 42, one side wall 423 of one coil 42 and another side wall 424 of the other coil 42 are facing each other. In the coupled inductor 40, the outer surface of the side wall 423 of the coil 42 located at one end is made approximately flush with the lateral surfaces 412c, 413c. An outer surface of the side wall 424 of the coil 42 located at the other end is made approximately flush with the lateral surfaces 412d, 413d. However, a position of the outer surface of the side wall 423 may be offset relative to the lateral surfaces 412c, 413c. Similarly, a position of the outer surface of the side wall 424 may be offset relative to the lateral surfaces 412d, 413d. In the coupled inductor 40, the upper surface of the upper wall 425 of the coil 42 is made approximately flush with the upper surfaces 412a, 413a. However, a position of the upper surface of the upper wall 425 may be offset relative to the upper surfaces 412a, 413a.

### <Connection Structure Between Coupled Inductor and Substrate>

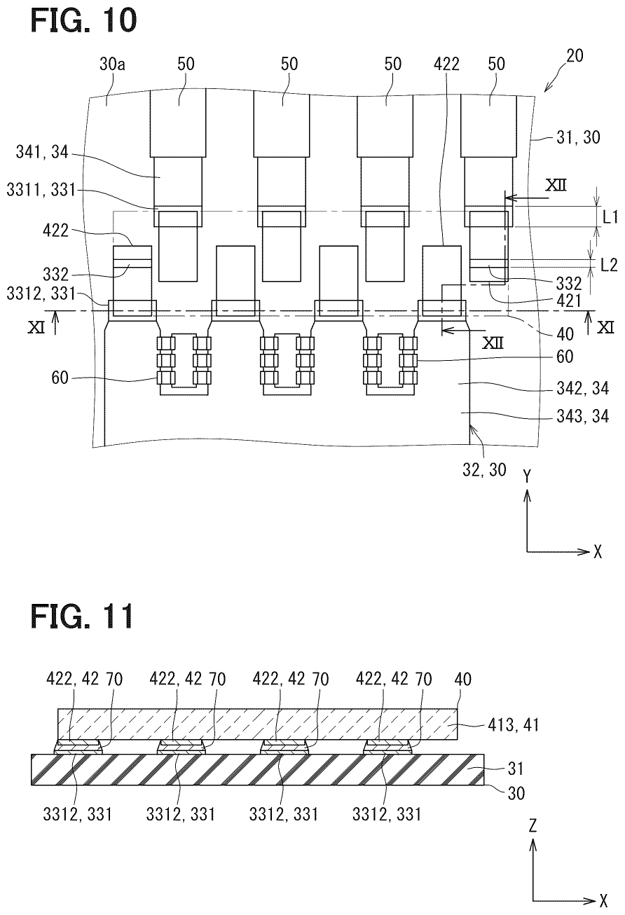

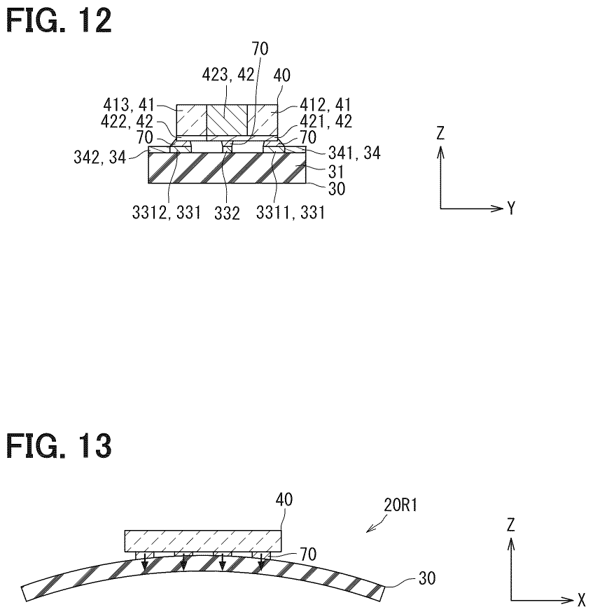

FIG. 10 is a diagram illustrating a positional relationship between the terminal of the coil and the land of the substrate. FIG. 10 corresponds to FIG. 3. However, an outline of the coupled inductor is indicated by a dash-dot-dash line. Of the coil, only the terminal is shown. In a plan view, the lands overlapping with the coupled inductor are also indicated by solid lines. FIG. 11 is a cross-sectional view taken along a line XI-XI of FIG. 10. FIG. 12 is a cross-sectional view taken along a line XII-XII of FIG. 10. In FIG. 11 and FIG. 12, for convenience, only the mounting lands of the conductors of the substrate are shown. In FIG. 10 to FIG. 12, the solder resist is omitted.

As described above, the land 33 has mounting lands 331 as the land 33 corresponding to the coupled inductor 40. The mounting lands 331 form a circuit together with the coil 42. The mounting lands 331 include a mounting land 3311 corresponding to the terminal 421 and a mounting land 3312 corresponding to the terminal 422. The mounting lands 331 include the same number of mounting lands 3311 as the terminals 421 and the same number of mounting lands 3312 as the terminals 422. The mounting lands 331 include four mounting lands 3311 and four mounting lands 3312, respectively. The number of mounting lands 3311 and 3312 is equal.

The four mounting lands 3311 are arranged in the X-direction with a predetermined interval. The four mounting lands 3312 are arranged in the X-direction with a predetermined interval. The mounting lands 3312 are provided offset in the X-direction relative to the mounting lands 3311. The mounting lands 3311 and the mounting lands 3312 are arranged in a staggered pattern or in a zigzag pattern. Among the eight mounting lands 3311 and 3312 arranged in the X-direction, one terminal 421 is positioned at one end, and one terminal 422 is positioned at the other end.

The mounting land 3311 is provided so as to overlap with a part of the terminal 421 in a plan view. At least a portion of the mounting land 3311 is positioned directly beneath the terminal 421. The mounting land 3312 is provided so as to overlap with a part of the terminal 422 in a plan view. At least a portion of the mounting land 3312 is positioned directly beneath the terminal 422. The mounting land 3311 is provided so as to overlap with a predetermined range of a portion from the end of the lateral surface 412f of the terminal 421. The mounting land 3312 is provided so as to overlap with a predetermined range of a portion from the end of the lateral surface 412f of the terminal 422.

The substrate 30 has at least one stress-relief land 332 as a land 33 corresponding to the coupled inductor 40. The stress-relief land 332 alleviates the stress acting on the solder joints of the mounting land 331. The stress-relief land 332 may also provide a wiring function. The stress-relief land 332 may be electrically connected to an inner layer wire 34, for example, through a via conductor. The stress-relief land 332 may also be one that does not provide a wiring function. In other words, the stress-relief land 332 may be configured not to be connected to other conductors 32. The stress-relief land 332 does not provide a wiring function.

The stress-relief land 332 is disposed on the surface layer of one side 30a of the substrate 30. The stress-relief land 332 is provided at a position that is separated from the mounting land 331 in a plan view. The stress-relief land 332 is provided in the Y-direction between the mounting land 3311 and the mounting land 3312, for example, near a midpoint between the mounting land 3311 and the mounting land 3312.

A single stress-relief land 332 may be joined to one of the terminals 421, 422, or it may be joined to the terminals 421, 422 that constitute the common coil 42. The stress-relief land 332 is provided so as to overlap with a part of the corresponding terminals 421, 422 in a plan view. At least a part of the stress-relief land 332 is positioned directly beneath the corresponding terminals 421, 422. The substrate 30 has two stress-relief lands 332. The stress-relief lands 332 are respectively provided directly beneath the terminals 421, 422 at both ends in the X-direction. One of the stress-relief lands 332 is positioned directly beneath the terminal 421 located at the end on the side of the lateral surfaces 412c, 413c. The other stress-relief land 332 is positioned directly beneath the terminal 422 located at the end on the side of the lateral surfaces 412d, 413d.

A planar shape and size of the stress-relief lands 332 are not particularly limited. The size refers to an area in a plan view. In the substrate 30, the mounting lands 311 and the stress-relief lands 332 have a substantially rectangular planar shape with the X-direction being a longitudinal direction. The size of one stress-relief land 332 is smaller than that of one mounting land 331. In the Y-direction, a length L2 of one stress-relief land 332 is longer than a length L1 of one mounting land 331.

The terminal 421 is joined to the corresponding mounting land 3311 via solder 70. The terminal 422 is joined to the corresponding mounting land 3312 via the solder 70. In the X-direction, the terminal 421, which is located at the end on the side of the lateral surfaces 412c and 413c, is joined to the stress-relief land 332 via the solder 70. The terminal 421, which is located at the end on the side of the lateral surfaces 412c and 413c, is joined to the mounting land 3311 and the stress-relief land 332. In the X-direction, the terminal 422, which is located at the end on the side of the lateral surfaces 412d and 413d, is joined to the stress-relief land 332 via the solder 70. The terminal 422, which is located at the end on the side of the lateral surfaces 412d and 413d, is joined to the mounting land 3312 and the stress-relief land 332.

In the connection structure between the aforementioned substrate 30 and the coupled inductor 40, an electric current flows in the following order: the wire 341, the mounting land 3311, the terminal 421, the side wall 423, the upper wall 425, the side wall 424, the terminal 422, the mounting land 3312, and the wire 342.

### <Summary of First Embodiment>

FIG. 13 is a diagram illustrating effects of substrate distortion in a reference example. FIG. 13 corresponds to FIG. 11. FIG. 13 is a simplified version of FIG. 11. In FIG. 13, the stress acting on the solder is indicated by solid arrows. In the reference example, a reference numeral for an electronic device is appended with an “R”.

In the electronic device 20R1 shown in FIG. 13, the substrate 30 differs from the electronic device 20 described in this embodiment in that it only has a mounting land 331 as a land 33 corresponding to the coupled inductor 40. The coupled inductor 40 has the same configuration as that of the electronic device 20 described in the present embodiment. The coupled inductor 40 has four coils 42 (not shown) arranged in the X-direction. As the number of coils 42 increases, the coupled inductor 40 becomes longer in the X-direction.

For example, if substrate warpage (bending) occurs such that the end of the substrate moves away from the center of the substrate where the coupled inductor 40 is mounted in the ZX plane, stress due to the substrate warpage will act on the solder 70. The stress acting on the solder 70 is greater the closer it is to the ends of the coupled inductor 40. Therefore, connection reliability of the solder 70 near the ends decreases.

The electronic device 20 of the present embodiment includes the substrate 30, the coupled inductor 40, and the solder 70. The coils 42 are arranged in a predetermined direction (X-direction) that is perpendicular to the thickness direction (Z-direction) of the substrate 30. The lands 33 soldered to the coils 42 are provided corresponding to the coils 42 and include the mounting lands 331 that, together with the coils 42, form a circuit, as well as at least one stress-relief land 332 provided at a position separate from the mounting lands 331. The coupled inductor 40 corresponds to an inductor component having the core 41 and the coils 42 arranged on the core 41.

In this manner, in addition to the mounting lands 331, the stress-relief land 332 is intentionally provided. By providing the stress-relief land 332, bonding points and bonding area of the coupled inductor 40 to the substrate 30 are increased. An amount of the solder 70 used to bond the substrate 30 and the coupled inductor 40 increases. By adding the stress-relief land 332, it is possible to adopt the coupled inductor 40 (inductor component) with the coils 42 aligned in a predetermined direction, while alleviating stress caused by substrate distortion and improving solder lifespan.

The stress-relief land 332 may be provided directly beneath any of the coils 42 included in the coupled inductor 40. The stress-relief land 332 may be provided, for example, directly beneath the coil 42 positioned near the center of the coupled inductor 40 in a predetermined direction. As illustrated, the stress-relief land 332 may be provided directly beneath the coil 42 located closer to the end of the coupled inductor than to the center of the coupled inductor in a predetermined direction. Since the stress acting on the solder 70 on the mounting land 331 near the end is greater due to substrate distortion, providing the stress-relief land 332 near the end can further improve the solder lifespan.

As illustrated, the stress-relief land 332 may be provided directly beneath the coil located at the end of the coils in a predetermined direction. The stress-relief lands 332 may be provided directly beneath the terminals 421 and 422 located at both ends in the predetermined direction. Since the mounting land 331, which experiences the greatest stress due to substrate distortion, and the stress-relief land 332 are joined to the same target, the solder lifespan can be further improved.

As illustrated, the stress-relief land 332 may be provided between a first mounting land and a second mounting land in the direction (Y-direction) perpendicular to both the plate thickness direction and the predetermined direction. One of the mounting lands 3311, 3312 corresponds to the first mounting land, and the other corresponds to the second mounting land. By providing the stress-relief land 332 between the mounting lands 3311 and 3312 in the Y-direction, the stress on the solder 70 on both the mounting land 3311 and the mounting land 3312 can be alleviated, thereby improving the solder lifespan.

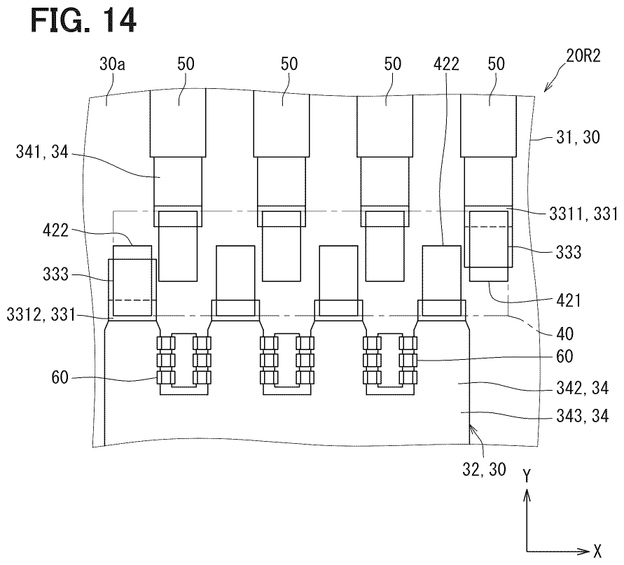

FIG. 14 is a diagram illustrating a positional relationship between a terminal and a land in another reference example. FIG. 14 corresponds to FIG. 10. In an electronic device 20R2 shown in FIG. 14, the mounting lands 3311 and 3312 are extended compared to the electronic device 20R1 in order to improve the connection reliability at the ends. The mounting lands 3311 and 3312 located at both ends in the X-direction have extension portions 333. The extension portions 333 are portions that extend further than the other mounting lands 3311 and 3312, and the boundaries of the extension portions 333 are indicated by broken lines. The extension portions 333 are larger than the mounting lands 3311 and 3312 that do not have the extension portions 333. In this way, by increasing an area of the mounting lands 3311 and 3312 at the ends where the stress is greater, it is possible to improve the connection reliability of the solder 70.

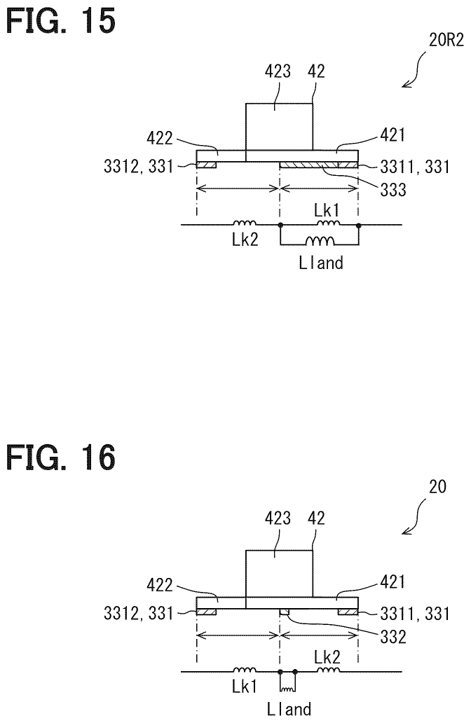

FIG. 15 is a diagram illustrating effects of parasitic inductance due to an extension portion in the reference example shown in FIG. 14. Here, in a case where the extension portions 333 are not provided, the inductance on the side of the mounting land 3311 up to a position of the extension portion 333 is denoted as Lk1, and the inductance on the side of the mounting land 3312 is denoted as Lk2. Additionally, the parasitic inductance due to the extension portions 333 is denoted as Lland. The parasitic inductance Lland is connected in parallel with the inductance Lk1. In a case where the extension portions 333 are not provided, the inductance Lk between the mounting lands 3311 and 3312 through the coil 42 is the sum of the inductances Lk1 and Lk2. The inductance Lk in a case where the extension portions 333 are provided is represented by equation (1).

Lk=(Lk1//Lland)+Lk2<Lk1+Lk2 (1)

A reciprocal of a first term (Lk1//Lland) on a right-hand side of equation (1) is equal to the sum of reciprocals of Lk1 and Lland. The first term on the right-hand side is smaller than the inductance Lk1. In other words, if the extension portions 333 are provided, the inductance Lk decreases, and the desired power supply characteristics cannot be obtained.

As illustrated, the stress-relief land 332 may be configured not to provide a wiring function on the substrate 30. Compared to a configuration in which the stress-relief land 332 is electrically connected to the mounting land 331 on the substrate 30, the influence of the parasitic inductance of the stress-relief land 332 on the inductance Lk can be reduced.

As illustrated, the stress-relief land 332 may be made smaller than the mounting land 331 in plan view. Since an area of one stress-relief land 332 is smaller than an area of one mounting land 331, the parasitic inductance of the stress-relief land 332 can be reduced. As a result, variations in the inductance Lk caused by the parasitic inductance of the stress-relief land 332 can be reduced.

As illustrated, a length L2 of the stress-relief land 332 in the Y-direction may be made shorter than a length L1 of the mounting land 331. As a result, the parasitic inductance of the stress-relief land 332 in one direction of current flow can be reduced. Therefore, variations in the inductance Lk can be effectively reduced.

FIG. 16 is a diagram illustrating effects of parasitic inductance due to the stress-relief land in the electronic device 20. In this electronic device 20, as shown in FIG. 10, the length L2 of the stress-relief land 332 is made sufficiently shorter than the length L1 of the mounting land 331. The length L2 is, for example, less than or equal to ½ of the length L1. As a result, the influence of the parasitic inductance Lland of the stress-relief land 332 can be almost ignored. The inductance Lk when such a stress-relief land 332 is provided is given by equation (2). As shown in equation (2), the reduction in inductance Lk due to the addition of the stress-relief land 332 can be effectively reduced.

Lk≈Lk1+Lk2 (2)

As illustrated, the electronic device 20 may be mounted on the substrate 30 and may include multiple switching devices 50 and capacitors 60, forming the multiphase power supply 10 together with the coupled inductor 40. The coupled inductor 40 may be placed between the switching device 50 and the capacitor 60 in the Y-direction. In a configuration where the coils 42 of the coupled inductor 40 are arranged in the X-direction, placing the switching device 50, the coupled inductor 40, and the capacitor 60 in the Y-direction simplifies wiring and helps to prevent an increase in size.

### <Modification>

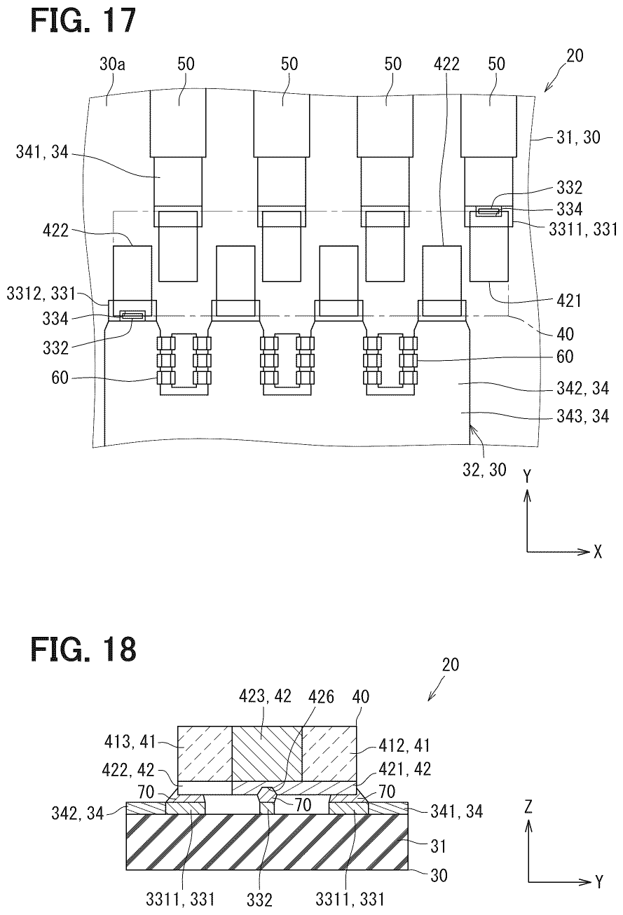

While the example has been shown where the stress-relief land 332 is provided between the mounting land 3311 and the mounting land 3312 in the Y-direction, the present invention is not limited to this configuration. For example, as shown in FIG. 17, a notch 334 may be provided in the mounting land 331, and the stress-relief land 332 may be placed within the notch 334. In FIG. 17, the notch 334 is provided at an end of the mounting land 3311 on a side of the wire 341. Similarly, the notch 334 is provided at an end of the mounting land 3312 on a side of the wire 342. FIG. 17 corresponds to FIG. 10.

### Second Embodiment

A second embodiment is a modification based on the fist embodiment, and the description of the first embodiment can be applied here. In the first embodiment, the lower surface of the terminal was flat. Instead of this, a recess may be provided on the lower surface of the terminal.

FIG. 18 is a cross-sectional view showing a vicinity of a coupled inductor in an electronic device according to the second embodiment. FIG. 18 corresponds to FIG. 12. As shown in FIG. 18, the terminals 421 and 422 located at both ends in the X-direction have recesses 426 on their lower surfaces. The recess 426 is provided in the terminal 421 located at the end on the side of the lateral surfaces 412c and 413c in FIG. 18. Although not shown in the figure, the recess 426 is also provided in the terminal 422 located at the end on the lateral surfaces 412d and 413d.

The recess 426 is provided at a position facing the stress-relief land 332. The recess 426 is provided at a position overlapping with the stress-relief land 332 in a plan view. The solder 70 that joins the coil 42 and the stress-relief land 332 is arranged in the recess 426. The solder 70 is filled in the recess 426 and is in contact with the bottom and lateral surfaces of the recess 426. The other configurations are the same as those described in the first embodiment.

### <Summary of Second Embodiment>

As illustrated, the coil 42 may have the recess 426 at a position facing the stress-relief land 332. The terminals 421 and 422 of the coil 42 may have the recess 426 at a position facing the stress-relief land 332. The solder 70 that joins the coil 42 and the stress-relief land 332 may be arranged in the recess 426. According to this, a contact area (bonding area) between the solder 70 and the coil 42 increases. Therefore, the solder lifespan can be further improved.

### Other Embodiments

When an element or layer is referred to as being “on,” “coupled,” “connected,” or “combined,” it may be directly on, coupled, connected, or combined to the other element or layer, or further, intervening elements or layers may be present. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. The description of A and/or B means at least one of A and B.

Spatially relative terms such as “inner,” “outer,” “back,” “below,” “low,” “above,” and “high” are utilized herein to facilitate description of one element or feature's relationship to another element(s) or feature(s) as illustrated. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in the other direction (rotated 90 degrees or in any other direction) and the spatially relative terms used herein are interpreted accordingly.

An example of the coupled inductor 40 is shown as an inductor component, but it is not limited to this. The inductor component is not limited to a configuration in which the coils 42 are arranged on the common core 41 and the coils 42 are magnetically coupled. The core 41 may be provided individually for each coil 42. The inductor component may, for example, be packaged in such a manner that the coils 42 are arranged in a predetermined direction.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. An electronic device comprising:
a substrate having lands;
an inductor component including cores and coils disposed on the cores, respectively; and
solder joining the coils and the lands, wherein
the coils are arranged in a first direction orthogonal to a thickness direction of the substrate, and
the lands joined to the coils include:
mounting lands provided correspondingly to the coils and forming a circuit together with the coils; and
at least one stress-relief land provided at a position separated from the mounting lands.

2. The electronic device according to claim 1, wherein
a coil is one of the coils, and
the stress-relief land is provided directly below the coil located closer to an end of the inductor component than to a center of the inductor component in the first direction.

3. The electronic device according to claim 2, wherein
the stress-relief land is provided directly below the coil located at an end of the coils in the first direction.

4. The electronic device according to claim 3, wherein
the coils have a first terminal and a second terminal as external connection terminals,
the mounting lands include:
a first mounting land joined to the first terminal; and
a second mounting land provided at a position different from the first mounting land in a second direction orthogonal to both the thickness direction and the first direction, and joined to the second terminal, and
the stress-relief land is located between the first mounting land and the second mounting land in the second direction.

5. The electronic device according to claim 4, wherein
the mounting lands have a wiring function on the substrate, and
the stress-relief land does not have the wiring function on the substrate.

6. The electronic device according to claim 5, wherein
the stress-relief land is smaller than the mounting lands in a plan view in the thickness direction.

7. The electronic device according to claim 6, wherein
a length of the stress-relief land is shorter than a length of the mounting lands in the second direction.

8. The electronic device according to claim 1, wherein
the coil has a recess at a position facing the stress-relief land, and
the solder joining the coil and the stress-relief land is disposed in the recess.

9. The electronic device according to claim 1, further comprising:
a switching device and a capacitor mounted on the substrate and configured to constitute a multiphase power supply together with the inductor component, wherein
the inductor component is disposed between the switching devices and the capacitors in a second direction orthogonal to both the thickness direction and the first direction.
